(19) United States
(12) Patent Application Publication
(10) Pub. No.: US 2018/0148826 A1
(43) Pub. Date: May 31, 2018

(54) Apparatus and Method for the Evaporation and Deposition of Materials Using a Rope Filament

(71) Applicant: Mustang Vacuum Systems, Inc., Sarasota, FL (US)

(72) Inventor: Robert W. Choquette, Sarasota, FL (US)

(73) Assignee: Mustang Vacuum Systems, Inc., Sarasota, FL (US)

(21) Appl. No.: 15/575,206

(22) PCT Filed: May 18, 2016
(86) PCT No.: PCT/US16/33068

§ 371 Date: Nov. 17, 2017

Related U.S. Application Data
(60) Provisional application No. 62/162,899, filed on May 18, 2015.

(51) Int. Cl. C23C 14/24; C23C 14/50; C23C 14/26

(52) U.S. Cl. CPC C23C 14/24; C23C 14/26; C23C 14/50

(57) ABSTRACT

An apparatus and method for the evaporation and deposition of materials onto a substrate. A source material may be attached to a rope filament inside a vacuum chamber. A mechanism may be controlled for heating the rope filament and evaporating the source material. Parts for coating may be loaded into a part carrier. A motor mechanism may be controlled for rotating the part carrier. The evaporated source material may be deposited on the parts in the part carrier. The rate of the deposition may be controlled in part by controlling the power source.

This application claims priority to U.S. Provisional Application 62/162,899 which is incorporated herein by reference, in its entirety.

### FIELD OF THE INVENTION

The presently disclosed invention relates in general to the field of vacuum deposition systems, and in particular to an apparatus and method for the evaporation of materials, such as aluminum and other metals and alloys.

### BACKGROUND

The present invention relates to an apparatus and method for evaporation and deposition using filaments. Previously known filament evaporation devices use multiple filaments connected between electrodes and wired in parallel, similar to plurality of resisters wired in parallel. One limitation of parallel filament designs is that individual filaments can have different operational lifetimes. When one filament breaks or requires renewal, only that one filament is replaced. The replacement filament, however, typically has different resistance than the remaining used filaments that have not yet been replaced, which can lead to inconsistent coating results, yellowing or burnt/dark parts that cannot be sold or used. Another limitation of parallel filament designs is that each individual filament requires its own set of connections and/or tensioners, each of which is a potential point of failure.

Further limitations exist with the multiple filament model in that the individual filaments are often installed in a mount and held in place by a high tension spring. The replacement of an individual filament, or multiple filaments, is labor intensive because of the difficulty in releasing and reengaging the high tension spring. The replacement process is further hindered by the limited space between the two ends of the individual filaments.

### SUMMARY OF THE INVENTION

The presently disclosed invention may be embodied in various forms, including but not limited to, apparatuses and methods for the evaporation and deposition of materials. One embodiment of the present invention addresses the existing limitations by providing an evaporation apparatus comprising an evaporation chamber. At least one part carrier is positioned inside the evaporation chamber to carry parts that are to be coated. A rope filament having a first end and second end is positioned proximate to the part carrier within the evaporation chamber. A first connector holds the first end of the rope filament and provides electrical current to it. A second connector adapted to hold said second end of said rope filament provides an electrical connection to a power return. The first connector and the second connector are operatively connected to a power source adapted to provide sufficient power to the rope filament to enable it to evaporate the source material and coat at least one part held by the part carrier.

An improved method of evaporative coating using an apparatus comprising a power supply, a rope filament, at least one part to be coated, and at least one source material is also provided. One embodiment of the method involves determining the characteristics of the rope filament, calculating the electrical output needed for the power supply to generate sufficient power to enable the rope filament to evaporate the source material, and adjusting the power supply to generate that electrical output. The rope filament may then be installed and the source material may be attached to it. At least one part is then loaded into the deposition apparatus. Power from the power supply may then be supplied, causing the rope filament to heat and evaporate the source material. After sufficient time to permit coating, the coated part may be retrieved from the deposition apparatus.

### BRIEF DESCRIPTION OF THE DRAWINGS

Other features in the invention will become apparent from the attached drawings, which illustrate certain preferred embodiments of the apparatus of this invention, wherein

FIG. 1 is a side view of one embodiment of a rope filament evaporation apparatus according to the present invention;

FIG. 2 is a perspective view of the upper section of the embodiment illustrated in FIG. 1;

FIG. 3 is a side view of the bottom section of the embodiment illustrated in FIG. 1;

FIG. 4 is a detailed side view of the lower filament connector of the embodiment illustrated in FIG. 1;

FIG. 5 is a detailed side view of the upper filament connector and the upper return connector of the embodiment illustrated in FIG. 1;

FIG. 6 is a perspective view of a prior art device with multiple filaments connected in parallel;

FIG. 7 is a side view of a portion of the device illustrated in FIG. 6.

FIG. 8 is a perspective view of an exemplary deposition apparatus.

FIG. 9 is an exploded, perspective view of a feed-through assembly for supplying power to the inside of a chamber of a deposition apparatus.

FIG. 10 is an exploded, perspective view of a filament pin top assembly for transferring power from the feed-through assembly in FIG. 9 and providing the power to a rope filament.

FIG. 11 is an exploded, perspective view of a filament tensioner for providing tension to a rope filament.

### DETAILED DESCRIPTION

While the following describes preferred embodiments of the present invention, it is to be understood that this description is to be considered only as illustrative of the principles of the invention and is not to be limitative thereof. Numerous other variations, all within the scope of the present invention, will readily occur to others in light of this disclosure.

The term “adapted” as used herein means sized, shaped, configured, dimensioned, oriented and arranged as appropriate.

The presently disclosed invention may be embodied in various forms, including but not limited to, apparatuses and methods for the evaporation and deposition of materials. One embodiment of the present invention addresses the existing limitations by providing an evaporation apparatus that utilizes a rope filament, which may conveniently be a tungsten rope filament, instead of multiple filaments wired in series or situated in parallel. The result is a more reliable apparatus that may provide more consistent coating results with fewer filament changes. The rope filament in embodiments of the present apparatus of the present invention may also allow the filament to evaporate source material in any direction, thereby also providing greater flexibility for multi-part-carrier embodiments.

In one embodiment, an apparatus for the deposition of materials onto a substrate may comprise a chamber capable of maintaining a vacuum. The embodiment may include a rotating part carrier for holding parts and facilitating a uniform deposition. The embodiment may further include a rope filament for evaporating a source material, such as aluminum. The source material may include any material capable of being evaporated. In some embodiments, the source material may be a metal or alloy typically used to coat parts. Those skilled in the art will recognize that these embodiments are merely exemplary and that any evaporative material is within the scope of the present invention. The rope filament may be a length substantially the same as the chamber, and may be held in place by a pair of connectors. Different filament characteristics may result in embodiments with different configurations. The characteristics of the filament, such as length or thickness, may change the overall resistance value of the filament, resulting in different power configurations or requirements. The characteristics of the filament may alter the characteristics of the ensuing deposition or coating of the parts. In some embodiments, the rope filament may be terminated on each end by a t-coupler or barrel connector.

In further exemplary embodiments, the top connector may be mounted in a fixed position and may include a shielded insulator to prevent electrical current from entering the body or frame of the apparatus. The t-coupler on one end of the rope filament may be secured into a connector at the top of a vertically arranged apparatus. The arrangement of the apparatus in the disclosed embodiments is merely exemplary in nature, and those skilled in the art will readily appreciate different arrangements or configurations and understand them to be within the scope of the invention. The bottom connector may include a tensioning device. The bottom connector may secure the other end of the rope filament by securing the barrel fitting on the opposite end into the connector, and the tensioning device would act to keep the rope filament straight during operation as the length of the filament may change.

An embodiment may also include a power return which connects to the tensioned end of the rope filament. In some embodiments, the power return may conveniently exit the apparatus proximate to the incoming power cable. In other embodiments, the power return may exit the apparatus in other locations. In one embodiment, a variable output transformer is connected to the apparatus to provide power to the fixed connector. Power is then provided to the rope filament through the insulated connector.

In an exemplary embodiment, a source material, such as aluminum, may be placed on a rope filament for evaporation. The source material may be comprised of aluminum or other metals or alloys, and may come in shapes and embodiments which facilitate attachment to the rope filament. For example, in one embodiment, the source material may come in a channel form, which can be secured over and around the rope filament. Source materials may be in any form capable of being attached to a rope filament. Those skilled in the art will understand the invention to include any form of source material, in addition to a channel form, such as a wire or wrap, that can be attached to a rope filament such that the source material is evaporated by the heat from the filament. Further, with a rope filament, the source material may be attached to the rope filament in various ways. For example, with channel type source material pieces, the pieces may be attached to the rope filament with equal distances between them. In further embodiments, the pieces may be attached to the rope filament so that there is no space in between the pieces of source material. Any number of configurations of attaching the source material to the rope filament are within the scope of the invention, and those disclosed within are merely exemplary.

Similarly, an embodiment of a method for the deposition of materials onto a substrate may comprise attaching source material onto a rope filament and controlling an electrical current through the rope filament to evaporate the source material. In addition, the method may comprise controlling the electrical current based on the length of the rope filament. Further, the method may comprise controlling the electrical current based on the complexity of substrates to be coated. The methods may also comprise controlling the electrical current based on the type, amount or configuration of the source material as it is attached to the rope filament.

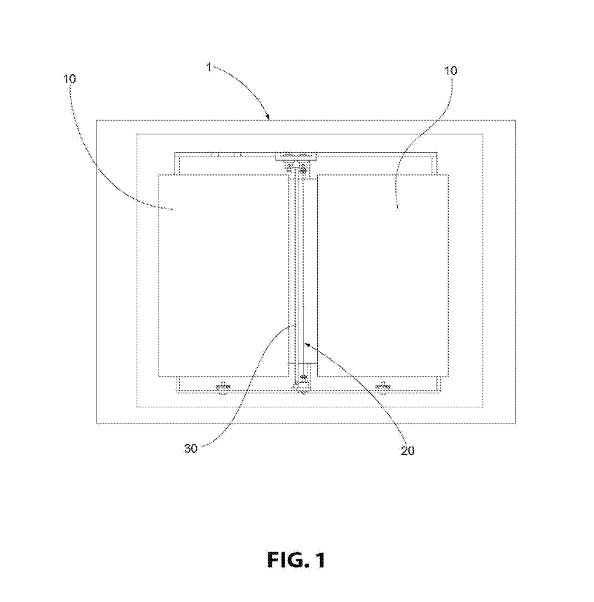

Referring now to the drawings, FIG. 1 shows an evaporation apparatus 1, with its outer door (not illustrated) removed. During operation, the outer door is closed and vacuum is typically maintained throughout the coating process. Evaporation apparatus 1 comprises two part carriers 10, rope filament 20 and return 30. Evaporation apparatus 1 may be used to evaporate source material (not illustrated) attached to rope filament 20 such that the material coats parts in part carriers 10, which may rotate during operation to allow uniform coating of multiple parts (not illustrated). Part carriers 10 in this embodiment are merely a representation of cylinders showing the physical area in which part carriers 10 would typically rotate. The physical configuration of part carriers 10 will depend on the size, shape and characteristic of the parts to be coated. Various embodiments of part carriers are thus known and can be used with the illustrated embodiment, including a skeleton or Christmas-tree-like part carriers (not illustrated) which are adapted to provide a plurality of supports extending from a central support from which parts may be hung. Such carriers tend to have a small surface area and otherwise facilitate the deposition process by providing minimal barriers between the source material and the parts to be coated. Those skilled in the art will appreciate the multiple embodiments possible of a deposition part carrier and understand their scope to be within the present invention. Similarly, it will be understood by those of skill in the art that, while the illustrated embodiment shows two part carriers 10, embodiments using one, two, three, four or more part carriers arranged around rope filament 20 are all possible. Where multiple part carriers 10 are used, a planetary rotating arrangement (not illustrated) may be used to further facilitate even coating.

High energy current is passed through rope filament 20 and return 30 in order to cause rope filament 20 to heat and thereby cause the source material to vaporize, thus emitting coating material that then deposits on parts in part carriers 10. In one exemplary embodiment, the high energy current may be provided by a variable output transformer (not illustrated). The output characteristics of the transformer will be depend on the resistance and other characteristics of rope filament 20. In one embodiment using a tungsten filament, the variable output transformer may provide 150 volts of alternating current (AC) at 150 amps. In other embodiments, the transformer may provide between 50 and 200 volts AC and between 50 and 250 amps. In some embodiments, a convenient AC frequency is 50-70 Hz.

While other materials known in the art may be used, rope filament 20 may conveniently be a multi-stranded tungsten filament formed as a rope. Such a tungsten rope filament is available from Midwest Tungsten Service, located at 540 Executive Drive, Willowbrook, Ill. 60527. When tungsten is used, rope filament 20 may conveniently be formed by twisting three tungsten yarns (not illustrated) into a strand (not illustrated), and then twisting three strands into a rope. While different variations may be used, the embodiment shown thus utilizes a rope filament 20 formed of nine tungsten yarns, each with an approximate diameter of 0.02″-0.03″. While single-strand, non-twisted filaments or braided filaments may be used, the twisted filament configuration is convenient due both to its ease of manufacture and the increased surface area over which melted source material may flow prior to evaporation.

The length of the rope filament 20 will vary depending on the configuration of the machine, but will typically be substantially the same length as part carriers 10. Having a single rope filament 20 that is substantially the same length as part carriers 10 has the advantage of allowing one filament to be used to coat parts at all levels in part carriers 10 without the need to use multiple filaments wired in parallel. Electrically, the use of a single rope filament performs like a circuit with a single resistor in series, as opposed to a circuit with multiple resistors (of potentially different resistance values) wired in parallel.

In one exemplary embodiment, the length of the rope filament 20 will be 51 inches. In other embodiments, the rope may be of different lengths, but will preferably be substantially the same length as the part carrier. Other suitable materials that could be used for rope filament 20 include tantalum or tungsten/tantalum blends and other alloys and materials typically used or suitable for high energy filaments. Those skilled in the art will readily recognize that any material with a resistance value such that an electric current can cause the material to heat up to the point where a source material could be evaporated, without immediately destroying the material itself, may be a suitable filament material within the scope of the present invention.

Sizing of the yarns and the number of yarns used in each strand and the number of strands that make up each rope may be based on the resistance of the filament material and can be changed to accommodate multiple materials and resistances, as will be understood by those of skill in the art. Accordingly, first the length of rope filament 20 is determined based on the size of part carriers 10 and the number, shape and configuration of the parts to be coated. Then the characteristics of the transformer used to power rope filament 20 can be identified. From that information, a desired resistance value can be determined, from which the number and thicknesses of the yarns and strands can be determined. Additional configuration details about the apparatus could also be used to determine the necessary parameters. For example, a part carrier 10 may have a length of 51 inches, whereby a filament length of 51 inches would be convenient. By tightening or loosening the twist, the total length of each yarn or each strand used can also be adjusted to result in a filament of a desired resistance value and total length.

The characteristics of the transformer may conveniently be based on the resistance of the rope filament 20. For example, once a length, thickness and material of a rope filament 20 are determined, the resistance may be calculated and the transformer output varied accordingly. For example, for a 51 inch length of tungsten filament with 9 yarns having a thickness of approximately 0.025″, a 43 kV transformer may provide power in the form of 100 to 200 volts at 100-200 amps of 60 Hz AC to achieve a rope filament temperature of approximately 1000 degrees Celsius. Those skilled in the art would recognize that other embodiments which use various source materials may require different temperatures for optimal deposition or coating and that the configuration of those alternate embodiments would be within the scope of the present invention.

For avoidance of doubt, in this disclosure “yarn” is used to refer to a single length of the desired filament material and “strand” is used to refer to a plurality of “yarns” twisted or braided together. A “rope” may be formed from a single thick wire, a plurality of yarns twisted into a single strand, or a plurality of strands formed into a rope. While twisting strands and yarns is convenient, in certain embodiments yarns and strands may also be braided. For further avoidance of doubt, in this disclosure, “rope” may also refer to wire rope or cable. With regard to metal materials, the term “cable” is used interchangeably with “wire rope” which this disclosure refers to as simply “rope.” For diameters less than ⅜″, it is common for the terms “cord” or “wire” to be used, for which this disclosure refers to as “yarn.” Following, a plurality of “wires,” “cords,” “threads,” or “yarns” may be used to create a “strand,” and a plurality of “strands” may be used to create a “cable,” “wire rope,” or “rope.” In this disclosure, the term “yarn” is not limited in any way to textiles or any materials whatsoever. Additionally, the terms “yarn”, “strand”, and “rope” are not limited to any size by definition. There may be many terms used to describe thin materials woven, braided, twisted or otherwise combined into larger structures, and all of those terms are understood to be within the scope of the present invention.

The gauge of the material used will impact the resistance value of the overall filament and its longevity. For further avoidance of doubt, the apparatuses and methods disclosed herein include both embodiments in which the rope filament is a strand formed of a plurality of yarns twisted or braided together, and embodiments in which a single continuous filament is formed of as a wire, rod or bar (referred to herein as a “wire filament”).

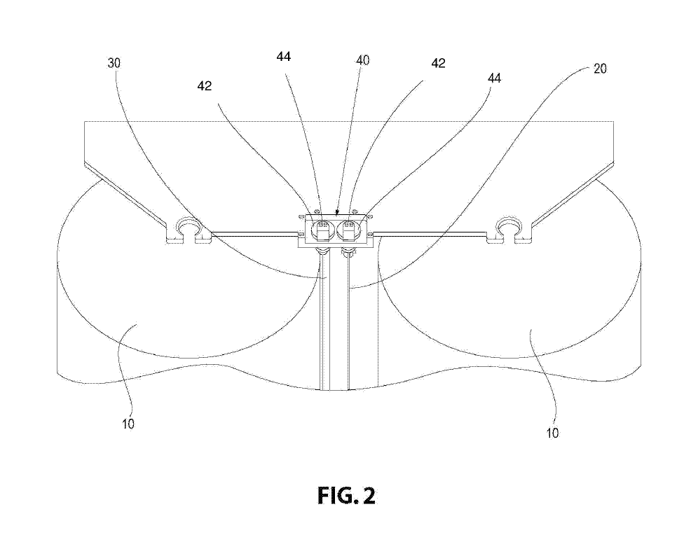

FIG. 2 illustrates a section of the upper portion of evaporation apparatus 1. Upper connector assembly 40 comprises insulated standoffs 42, one of which provides an electrical connection to rope filament 20, and the other of which provides an electrical connection to power return 30. Insulated standoffs 42 allow rope filament 20 and return 30 to be electrically connected to a high power transformer (not illustrated) suitable for generating the power necessary for evaporative coating, with return 30 preferably being connected to the common leg of the transformer (not illustrated). Blade style contacts 44 may conveniently be used to transfer the power, but other contact designs known in the art can also be used. While other materials known in the art can be used, as illustrated, insulated standoffs 42 are formed of Phenolic, Ultem or Kapton material, but can also be made of other materials.

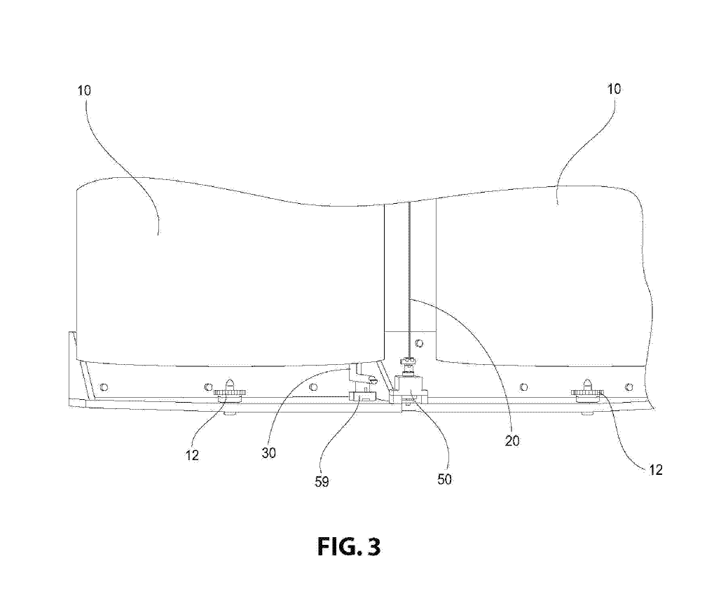

FIG. 3 illustrates the bottom portion of evaporation apparatus 1. Part carriers 10 may rotate, preferably driven by electric motors (not illustrated) that drive gear sets 12. Rope filament 20 is connected to bottom filament holder 50 which may conveniently be of the same materials and design as insulated standoffs 42 previously discussed. Return 30 similarly connects to bottom return holder 59.

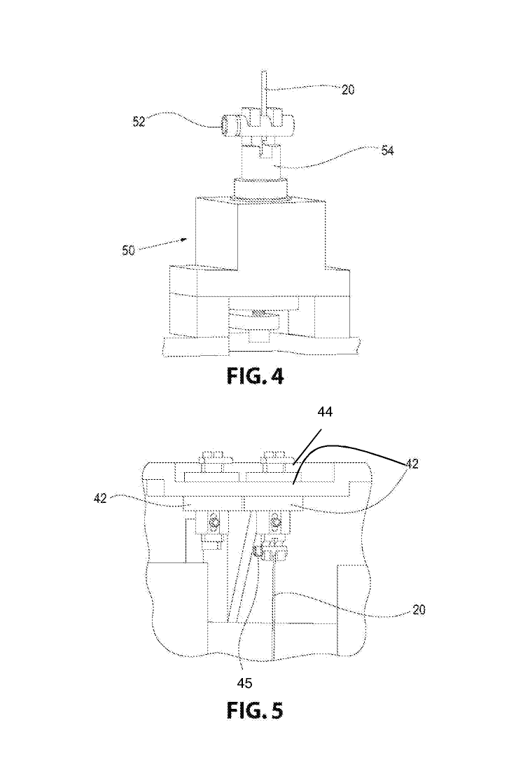

FIG. 4 illustrates bottom filament holder 50 in further detail. As shown, lower t-coupler 52 holds the bottom end of filament 20. While other connection means are possible (including without limitation clamps, crimps, and other mechanical securing means), in the illustrated embodiment a set screw (not illustrated) is used to secure lower t-coupler 52 to rope filament 20. Spring tensioner 54 is adapted to maintain appropriate tension on rope filament 20 as its length can grow as a result of evaporation.

FIG. 5 illustrates insulated standoffs 42 in further detail. Similar to bottom filament holder 50, one illustrated standoff 42 comprises upper t-coupler 45 (which may conveniently be attached to rope filament 20 as described above) for holding the upper end of rope filament 20. Using upper t-coupler 45 and lower t-coupler 52 in combination with spring tensioner 54 is convenient as they allow faster and easier installation and replacement of rope filament 20 with minimal tools.

In operation, power is supplied by a transformer and flows through rope filament 20 and back through return 30, thereby heating rope filament 20 to a temperature sufficient to evaporate a source material (not illustrated) and cause it to emit coating particles (not illustrated). As part carriers 10 rotate, parts (not illustrated) within part carriers 10 are exposed to the coating particles. Because of the design of rope filament 20, it has a comparatively longer life and tends to emit evenly across its entire length until it needs to be replaced, as a whole.

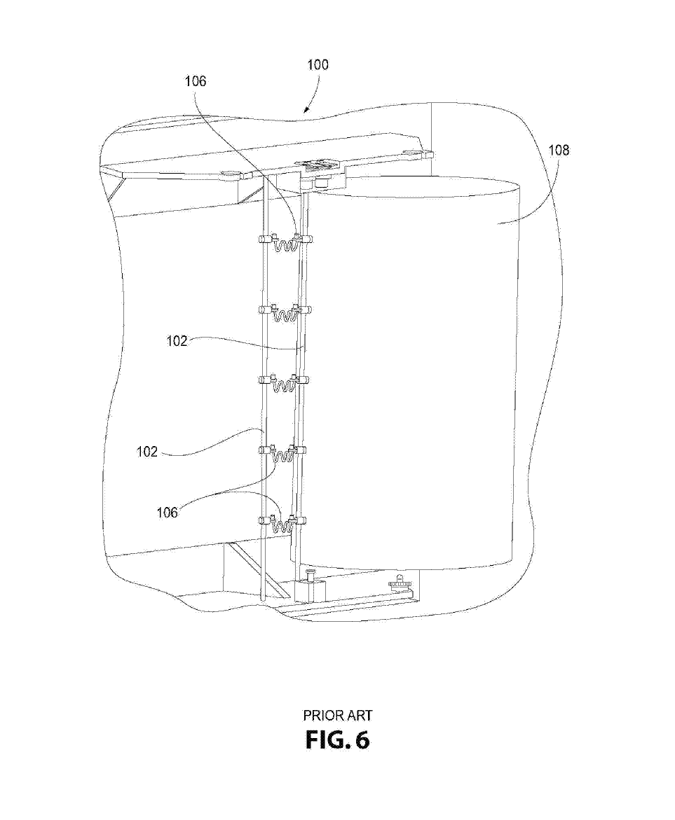

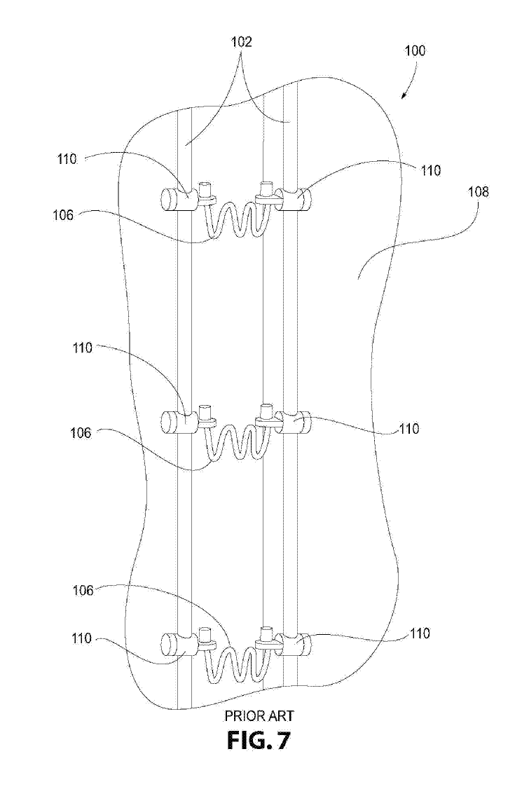

Rope filament evaporation apparatuses, according to the present invention, have advantages over prior art parallel filament apparatuses, such as apparatus 100 illustrated in FIGS. 6 and 7. Single part carrier 108 holds parts (not illustrated) to be coated. Electrodes 102 are arranged in parallel and are connected to a transformer (not illustrated). In a typical embodiment of prior art parallel filament apparatuses, a transformer may provide a 15 v current at between 1000-1500 amps due in part to the parallel resistor configuration of filaments 106. The parallel configuration requires a higher current output than embodiments of the present invention. A plurality of filaments 106 are connected in parallel between electrodes 102. Connectors 110, which may contain tensioning springs (not illustrated) connect filaments 106 to electrodes 102. As power is applied to electrodes 102, source material on filaments 106 evaporate to emit coating particles.

With the parallel filament design, filaments 106 may have varying operational lifetimes. Over that lifetime, the resistance of each filament 106 will change. Thus, when one filament 106 requires replacement, and a new filament 106 is inserted, the new filament 106 will have a different resistance than the remaining older filaments 106 that have not been replaced. The result can be broken filaments, yellowing, dark spots, uneven coating and a higher number of waste parts that received poor quality coating. In addition, the designs of connectors 110 are typically such that replacement takes time and requires tools, thereby increasing downtime during filament changes. Further, connection points, such as provided by connectors 110, are common points of failure. Having two connectors 110 for each filament 106 thereby creates multiple failure points for the apparatus. Apparatuses, according to the present invention, address those, and other, limitations of the parallel filament design by providing a longer life filament that evaporates comparatively evenly throughout its operational life, and is easier and faster to replace.

It will be further understood that the color of the coating can be further adjusted by varying parameters within the evaporation chamber. By way of example, and without limitation, increasing the vacuum in the chamber will tend to result in brighter reflective color, while decreasing the vacuum in the chamber will tend to result in darker colors. Increasing power levels during evaporation can also promote a brighter metallic color, while reducing evaporation power will reduce the brightness of the metallic film. A typical evaporation chamber will have a vacuum pressure of 2.5×10⁻⁴ Torr. For more complex parts to be coated, the vacuum pressure may be lowered to 2.5×10⁻⁵ Torr.

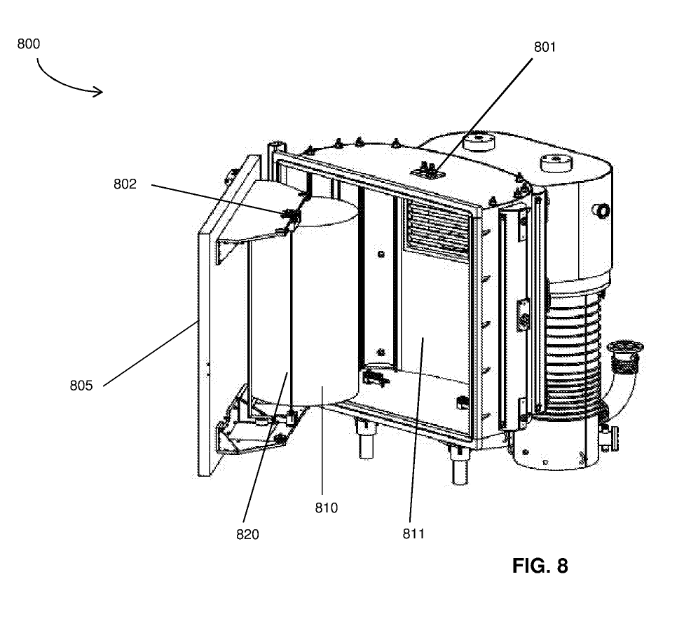

In some embodiments, it may be convenient to feed electrical power through the outside of a vacuum chamber to the filament on the inside, thereby allowing more of the power supply to remain outside the vacuum chamber. Referring to FIG. 8, an embodiment of an evaporation apparatus has vacuum chamber 811. Door 805 is adapted to hold a single rope filament 820. At the top of chamber 811 feed-through assembly 801 provides electrical power to the interior of chamber 811 when door 805 is closed and vacuum is drawn. At the top of door 805, a filament pin assembly 802 is positioned a distance generally half of the width of chamber 811 from door 805. This embodiment is merely exemplary and not limitative of the present invention. Those skilled in the art will recognize that multiple configurations capable of forming a vacuum chamber exist and are within the scope of the present invention. The filament pin assembly 802 connects to feed-through assembly 801 to provide electrical power to single rope filament 820. In the illustrated embodiment, single rope filament 820 is positioned proximate to part carrier 810, which may conveniently be adapted to rotate during operation. While the illustrated embodiment uses feed-through assembly 801 which connects to filament pin assembly 802 when door 805 is closed, in other embodiments (not illustrated), the entire evaporative apparatus and power connection assembly may be attached to a door, thereby eliminating the need for a contact connection between filament pin assembly 802 and feed-through assembly 801. Having part carrier 810 and rope filament 820 on door 805 is convenient as it allows more room for par loading and filament changes when door 805 is open. Of course, embodiments in which rope filament 820 and part carrier 810 are within chamber 811 (as opposed to on door 805) are also possible.

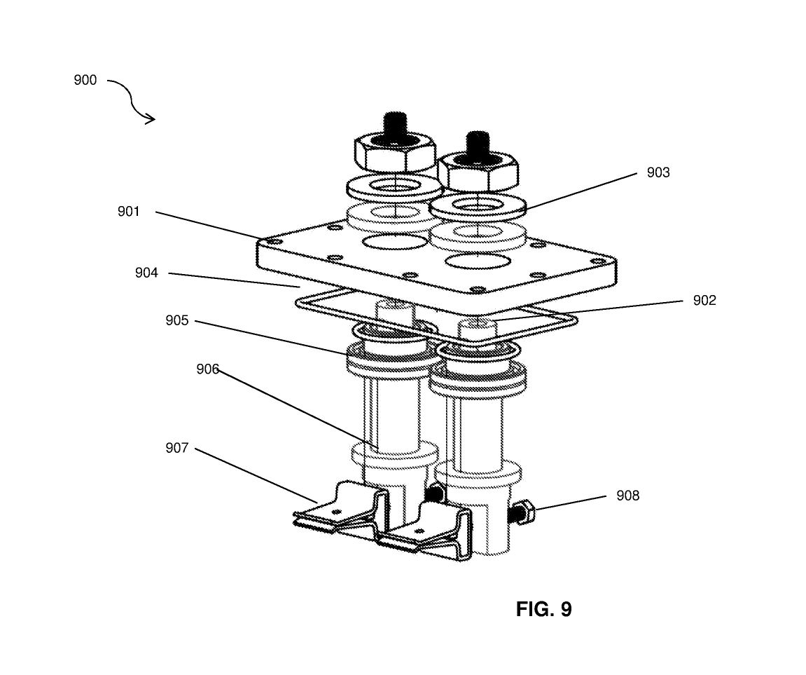

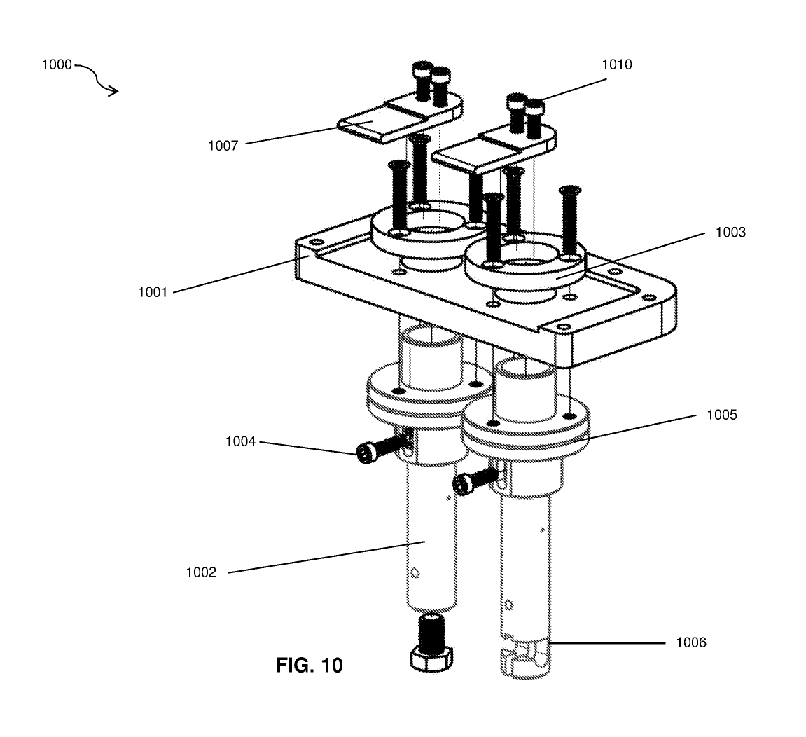

In the illustrated embodiment, the electrical power may pass from outside the body of the chamber 811 to the single rope filament 820 inside the chamber when door 805 is closed, while preserving the convenience of rope filament 820 and part carrier 810 being attached to door 805. In some embodiments, this may be accomplished by a two part feed-through assembly with one part attached to the chamber surface and one part attached to the door. In the embodiment illustrated in FIG. 8, power from a transformer (not illustrated) passes through feed-through assembly 801 into the filament pin top assembly 802 which is attached to door 805. When the door is open, there is no electrical connection between feed-through assembly 801 and filament pin top assembly 802, thereby creating a further safety advantage. When the door 805 is closed, an electrical connection between feed-through assembly 801 and filament pin top assembly 802 is created by a mating of blade connectors to adapted fuse holders (illustrated in FIGS. 9 and 10). The connection apparatus described herein is merely exemplary in nature and those skilled in the art will readily recognize that multiple embodiments for passing electricity into a vacuum chamber exist and are within the scope of the present invention.

Referring now to FIG. 9, a feed-through assembly 900 for passing electricity through a chamber wall is illustrated. Feed-through assembly 900 is mounted to a chamber wall, such as illustrated in FIG. 8. Feed-through assembly 900 is mounted to a chamber with mounting plate 901 and feed-through posts 902. Feed-through posts 902 pass up through the chamber wall (not illustrated) and are tightened against mounting plate 901 by a threaded shaft tightened into feed-through posts 902 and secured with a nut and washer on the exterior of mounting plate 901. The conductive parts of feed-through assembly 900 may be made of any conductive material, however, they may be conveniently made of copper or brass. Additionally, insulating parts 903, 905 of feed-through assembly may be made of any insulating material, and conveniently may be made of Phenolic, Ultem or Kapton. An insulator collar 903 prevents the electricity passing through feed-through posts 902 from coming in contact with mouthing plate 901, and thus the rest of the apparatus, thereby improving safety and efficiency. Additionally, many methods, techniques and devices for insulating electrical connections from apparatus bodies and frames are well known in the art and all are within the scope of the present invention.

A gasket 904 may be included between mounting plate 901 and the chamber wall to seal the chamber around the feed-through assembly 900. An insulator flange 905 prevents the electricity passing through feed-through posts 902 from coming into contact with the bottom side of a chamber wall. At the end of feed-through posts 902, a filament feed-through 906 is attached. Filament feed-through 906 allows electricity to pass through feed-through posts 902 into electrical receptacle 907. In some embodiments, the electrical receptacle may be a fuse holder or fuse block adapted to receive a blade connector (illustrated in FIG. 10). FIG. 9 illustrates two filament feed-through 906 in a side by side configuration. The second filament feed-through is conveniently located near the first for a power return. The power return connection may be located near the power supply line for a convenient configuration. However, multiple configurations for the location of the power return are within the scope of the present invention.

Referring now to FIG. 10 filament pin top assembly 1000 is illustrated. Filament pin top assembly 1000 may conveniently be attached to a door structure of a single rope filament deposition apparatus (illustrated in FIG. 8). Electricity passes through the feed-through assembly illustrated in FIG. 9 and into filament pin top assembly 1000. Filament pin top assembly 1000 is mounted to a structure on the chamber door by a filament pin top plate 1001. Filament pin top plate 1001 is secured on the top portion of the door structure to allow the top portion of filament pin top assembly 1000 to come into electrical contact with the feed-through assembly of FIG. 9. Filament pin top plate 1001 is secured to a door structure. Insulating collars 1003 are screwed down through filament pin top plate 1001 and through the door structure into insulating flanges 1005. The insulator assembly prevents the electrical power from coming into contact with the door structure, thereby increasing safety and efficiency. The conductive parts of filament pin top assembly 1000 may be made of any conductive material, however, they may be conveniently made of copper or brass. Additionally, insulating parts of filament pin top assembly may be made of any insulating material, and conveniently may be made of Phenolic, Ultem or Kapton. Additionally, many methods, techniques and devices for insulating electrical connections from apparatus bodies and frames are well known in the art and all are within the scope of the present invention. Insulator flanges 1005 and insulating collars 1003 allow filament post 1002 to pass up through the insulator assembly and door structure without creating an electrical connection with the apparatus structure.

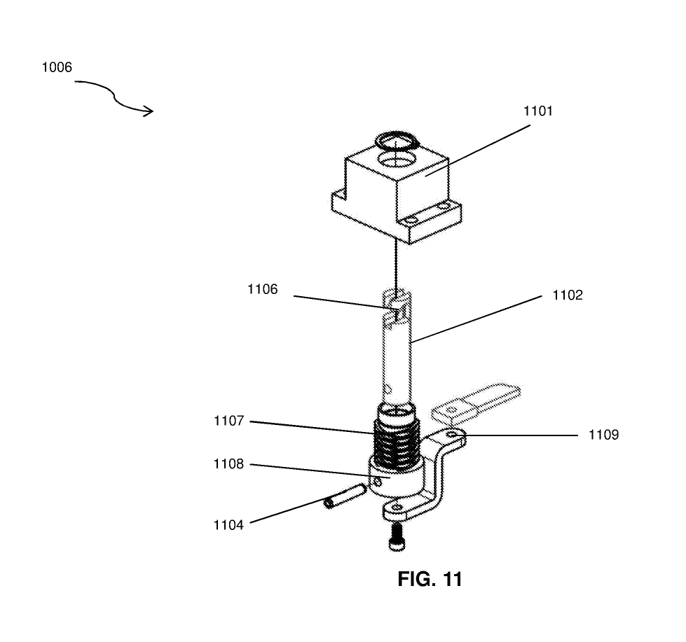

Filament post 1002 passes up through the chamber door structure, through the insulator assembly and filament pin top plate 1001. Blade connectors 1007 are attached to filament post 1002 at the top via screws 1010. FIG. 10 illustrates two filament posts 1002 in a side by side configuration. The second filament post is conveniently located near the first for a power return. The power return connection may be located near the end of the rope filament for a convenient configuration. However, multiple configurations for the location of the power return are within the scope of the present invention. The power return filament post 1002 may be connected to a conductive contact tab (illustrated in FIG. 11). A set screw 1004 secures filament post 1002 into insulator flange 1005. Filament post 1002 connects to a single rope filament via barrel connector 1006, which may conveniently be formed from copper or brass, although other materials with conductive properties may be used. The end of a single rope filament may terminate in a barrel or nipple cable fitting. The barrel or nipple cable fitting will fit into barrel connector 1006. The barrel or nipple type cable fitting and receptacle are merely exemplary embodiments of a connection between a removable rope filament and a connector. Other methods, techniques and devices for a removable electrical connection are known in the art and within the scope of the present invention. The single rope filament will be secured to filament post 1002 via the barrel fitting. Force to keep the connection tight and minimize movement of the cable fitting in fitting receptacle 1006 is provided by a tensioner (illustrated in FIG. 11) installed at the location of the opposite end of the single rope filament.

Referring now to FIG. 11, filament tensioner 1100 is illustrated. Filament tensional 1100 operates to keep the single rope filament (not illustrated) tight by providing tension between filament pin top assembly illustrated in FIG. 10 and the bottom end of the door structure illustrated in FIG. 8. This embodiment is merely exemplary and not limitative of the present invention. Those skilled in the art will recognize that multiple configurations of a vacuum chamber exist and are within the scope of the present invention. The filament tensioner 1100 is secured to a similar door structure as the filament pin top assembly as illustrated in FIG. 8. Filament tensioner 1100 is attached to the lower door structure by an insulated filament holder 1101. Insulated filament holder 1101 has a hole in the middle for which lower filament rod 1102 extends up through and is held in place by a retaining ring. The conductive parts of filament tensioner 1100 may be made of any conductive material, however, they may be conveniently made of copper or brass. Additionally, insulating parts of filament tensioner 1100 may be made of any insulating material, and conveniently may be made of Phenolic, Ultem or Kapton. Additionally, many methods, techniques and devices for insulating electrical connections from apparatus bodies and frames are well known in the art and all are within the scope of the present invention.

Lower filament rod 1102 is terminated on an upper end by a barrel connector 1106. The end of a single rope filament may terminate on the lower end with barrel or nipple cable fitting (not illustrated). The barrel or nipple cable fitting will fit into barrel connector 1106. The single rope filament will be secured to lower filament rod 1102 via the barrel fitting. Force to keep the connection tight and minimize movement of the cable fitting in fitting receptacle 1106 is provided by filament tensioner 1100. The barrel or nipple type cable fitting and receptacle are merely exemplary embodiments of a connection between a removable rope filament and a connector. Other methods, techniques and devices for a removable electrical connection are known in the art and within the scope of the present invention.

The lower end of lower filament rod 1102 is secured into lower rod insulator 1108 with pin 1104. Lower rod insulator 1108 prevents the electrical current passing through lower filament rod from passing into the mounting structure of filament tensioner 1100 and the lower door structure. This embodiment is merely exemplary and not limitative of the present invention. Those skilled in the art will recognize that multiple configurations of a vacuum chamber exist and are within the scope of the present invention. The tensioning mechanism spring 1107, which is positioned around the narrower diameter of lower rod insulator 1108. Spring 1107 is compressed between insulated filament holder 1101 and the wider diameter of the lower end of lower rod insulator 1108. When fully assembled, insulated filament holder 1101 is screwed or bolted down to the lower door structure such that lower filament rod 1102 passes up through insulated filament holder 1101 and attaches to the single rope filament (not illustrated) and spring 1107 is compressed, providing force and pulling the single rope filament toward the lower end. This acts to keep the single rope filament tight as it heats up, because the single rope filament may lengthen or shorten based on the temperature. If the tensioner does not keep it straight, the single rope filament may curve or bow, causing non-uniform evaporation of the source material, which leads to defects in the resulting deposition. At the lower end of lower filament rod 1102, conductive contact tab 1109 is attached. Conductive contact tab 1109 allows a power return to be attached. Other methods, techniques and devices for returning power in an electrical circuit are known in the art and all are within the scope of the present invention.

While the invention has been particularly shown and described with reference to an embodiment thereof, it will be understood by those skilled in the art that various changes in form and details may be made therein without departing from the spirit and scope of the invention.

1. An apparatus for evaporative coating comprising:
an evaporation chamber;
at least one part carrier positioned inside said evaporation chamber;
a tensioned rope filament having a first end and second end positioned proximate to said part carrier;
a source material in contact with said rope filament;
a first connector adapted to hold said first end of said rope filament for providing electrical current to said rope filament;
a second connector adapted to hold said second end of said rope filament; and,
an electrical power return connected to a power source and connected to said second connector.

2. The apparatus of claim 1 wherein said source material comprises a metal.

3. The apparatus of claim 1 comprising a plurality of said rotating part carriers arranged about said rope filament.

4. The apparatus of claim 3 further comprising a planetary gear set adapted to allow said rotating part carriers to rotate around said rope filament while said part carriers individually rotate.

5. The apparatus of claim 1 wherein said first connector and said second connectors are t-couplers.

6. The apparatus of claim 4 wherein at least one said t-coupler is adapted to attach to a spring tensioner adapted to maintain tension on said rope filament as the length of said rope filament changes due to evaporation.

7. The apparatus of claim 1 wherein said rope filament comprises a strand comprising a plurality of yarns twisted or braided together.

8. The apparatus of claim 1 wherein said rope filament consists essentially of a wire filament.

9. The apparatus of claim 1 wherein said rope filament is formed of tungsten.

10. The apparatus of claim 1 wherein said rope filament is formed of a tungsten alloy.

11. The apparatus of claim 1 further comprising a plurality of rope filaments and a plurality of part carriers wherein one said rope filament is proximate to each said part carrier.

12. The apparatus of claim 1 comprising a single rope filament and a single part carrier.

13. A method of evaporative coating using a deposition apparatus comprising a power supply, a tensioned rope filament, a part carrier having substantially the same length as said rope filament, at least one part to be coated in said part carrier, and at least one source material, said method comprising the steps of,
determining the characteristics of said rope filament,
calculating the electrical output for said power supply,
adjusting said power supply for said electrical output,
installing said rope filament,
attaching said source material to said rope filament,
loading said at least one part into said deposition apparatus,
applying power to said deposition apparatus from said power supply causing said rope filament to heat and evaporate said source material, and,
retrieving coated parts from said deposition apparatus.

14. The method of claim 13 wherein said rope filament comprises a strand comprising a plurality of yarns twisted or braided together.

15. The method of claim 13 wherein said rope filament consists essentially of a wire filament.

16. The method of Claim 13 wherein said source material comprises a metal.

17. The method of claim 13 wherein said characteristics of said desired rope filament comprise the length of said rope filament.
